(19) United States
(12) Patent Application Publication
(10) Pub. No.: US 2026/0219318 A1
(43) Pub. Date: Jul. 30, 2026

(54) On-Chip Edge Alignment Controller

(71) Applicant: Google LLC, Mountain View, CA (US)

(72) Inventors: Mayank Parasrampuria, Bangalore (IN); Rajesh Gottumukkala, Bangalore (IN)

(21) Appl. No.: 19/143,648

(22) PCT Filed: Dec. 28, 2022
(86) PCT No.: PCT/US2022/054155

§ 371 Date: Jun. 26, 2025

(51) Int. Cl. G01R 31/317; G01R 31/3185

(52) U.S. Cl. CPC G01R 31/31726; G01R 31/318552

(57) ABSTRACT

Methods, systems, and apparatus, for aligning clock edges of a plurality of on-chip clock controllers. One of the methods includes receiving, by an on-chip edge alignment controller, a scan enable signal. A counter is incremented using a fastest clock among a plurality of on-chip clock controllers. When the counter reaches a value that is based on a least-common multiple between the fastest clock and a slowest clock, a trigger output value is generated on a trigger output port.

### BACKGROUND

This specification relates to synchronizing clocks for the purpose of testing timing paths between clock domains at-speed.

As chip designs become more complex, it is important to conduct testing of the timing between chip components. At-speed testing conducted at system speeds requires an at-speed clock to deliver timing for tests.

A single chip design can have multiple components running on different synchronous clock domains. On-chip clock controllers (OCCs) control clock waveforms. To conduct at-speed testing of paths between different clock domains, the clock edges for different clock domains should be aligned.

However, conventional systems for synchronizing OCCs have limitations which make them impractical to implement. For example, some systems produce unpredictable OCC output clocks. Others only support clocks having a power of two relationship, or can only support clocks having a power of two relationship that is smaller than a particular divided clock relationship value. Others require all lower divided clocks as inputs when a higher divided clock is used in the design. Additionally, other systems cannot synchronize OCCs across different physical partitions.

### SUMMARY

This specification describes an on-chip edge alignment controller (OEAC) that can synchronize OCCs of different clock frequencies. The OEAC can receive signals indicating a slowest clock and fastest clock among a plurality of OCCs. The OEAC can use a counter and a value that is based on a least-common multiple between the slowest and fastest clock to generate trigger signals to cause the different OCCs to have outputs that are edge-aligned or substantially edge-aligned within a particular threshold.

Particular embodiments of the subject matter described in this specification can be implemented so as to realize one or more of the following advantages. The OEAC can use the slowest and fastest functional clocks, and a counter that works on the fastest functional clock, to control when to generate trigger signals to synchronize different OCCs. Therefore, the OEAC can generate trigger signals to cause the different OCCs to have predictable outputs and have desired or sufficient edge alignment for at-speed testing of paths between clock domains. The sufficiency of the edge alignment may be based on a particular threshold alignment for a given at-speed test.

The OEAC can control different OCCs with clock frequencies of arbitrary ratios, not just powers of two, using the least-common multiple between the fastest clock and slowest clock. The OEAC only requires the slowest and fastest functional clock. Thus, other intermediate clock frequencies do not need to be supplied.

The counter allows the OEAC to have complete control over the start of clock signals and removes uncertainty of the OCC outputs. In addition, the counter size can be increased to support any arbitrary synchronous clock combinations. Thus, the OEAC is reconfigurable to support clocks that have higher divided clock relationship values.

Furthermore, the OEAC does not include OCCs, so the OEAC can control OCCs sitting across different physical partitions. The physical location of the OEAC relative to the OCCs is not fixed, and the trigger signals can be pipelined and sent across different physical partitions to control OCCs present in different physical partitions. Thus, there are no restrictions on where the OEAC and OCCs are arranged relative to each other on the chip.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a diagram of an example OEAC system.

FIG. 2 is a flowchart of an example process for synchronizing OCCs.

FIG. 3 is a diagram of example synchronized clock pulses.

FIG. 4 is a diagram of an example OEAC system that can synchronize OCCs across physical partitions.

Like reference numbers and designations in the various drawings indicate like elements.

### DETAILED DESCRIPTION

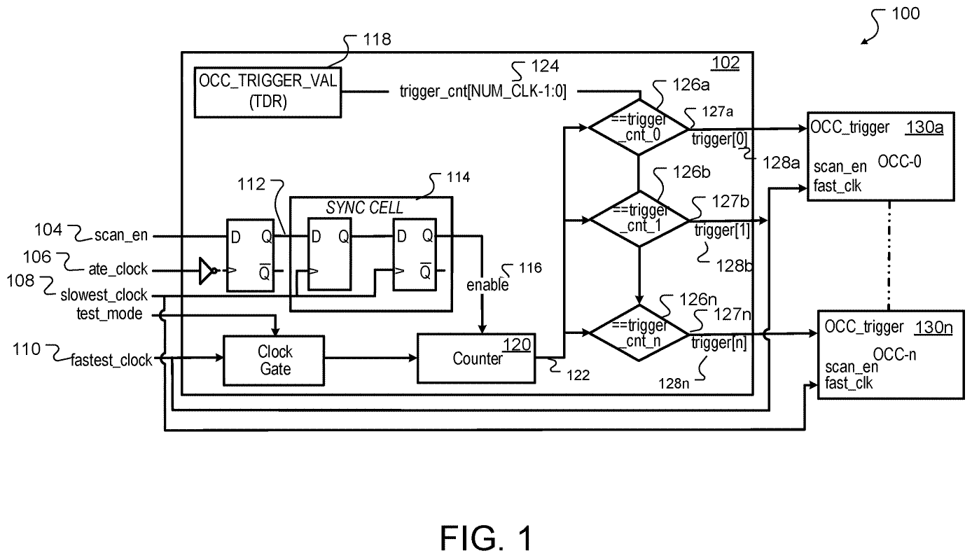

FIG. 1 is a diagram of an example OEAC system 100. The OEAC system 100 includes an OEAC 102 that can control multiple OCCs, e.g., OCC-0 130a . . . OCC-n 130n (collectively, “OCCs 130”).

The OCCs 130 can control clock waveforms. In the OEAC system 100 each of the OCCs 130a-n can control a clock waveform of a certain frequency by generating synchronous clocks. To perform at-speed testing of paths between clock domains, the output of each of the OCCs 130a-n must be substantially edge-aligned within a particular threshold. The OEAC 102 can synchronize the OCCs 130 and can guarantee sufficient edge alignment of the output of the OCCs 130.

The OEAC 102 can receive a clock signal from automated test equipment (ATE), “ate_clock” 106, and a scan enable signal, “scan_en” 104. The OEAC 102 can sample the scan enable signal 104 on the ATE clock signal 106 to produce a sampled scan enable signal 112. The slowest clock signal, “slowest_clock” 108, is the clock signal having the lowest frequency among the OCCs 130. The OEAC 102 includes a sync cell 114 that receives the sampled scan enable signal 112 and the slowest clock signal 108. The sync cell 114 can synchronize the sampled scan enable signal 112 with the slowest clock signal 108 to generate an enable signal, “enable” 116.

The fastest clock signal, “fastest_clock” 110, is the clock signal having the highest frequency among the OCCs 130. After the sync cell 114 sends the enable signal 116 to a counter 120, the counter 120 can start incrementing, working on the fastest clock signal 110. The counter 120 can count the number of cycles of the fastest clock signal 110 and output the count via a counter value signal 122.

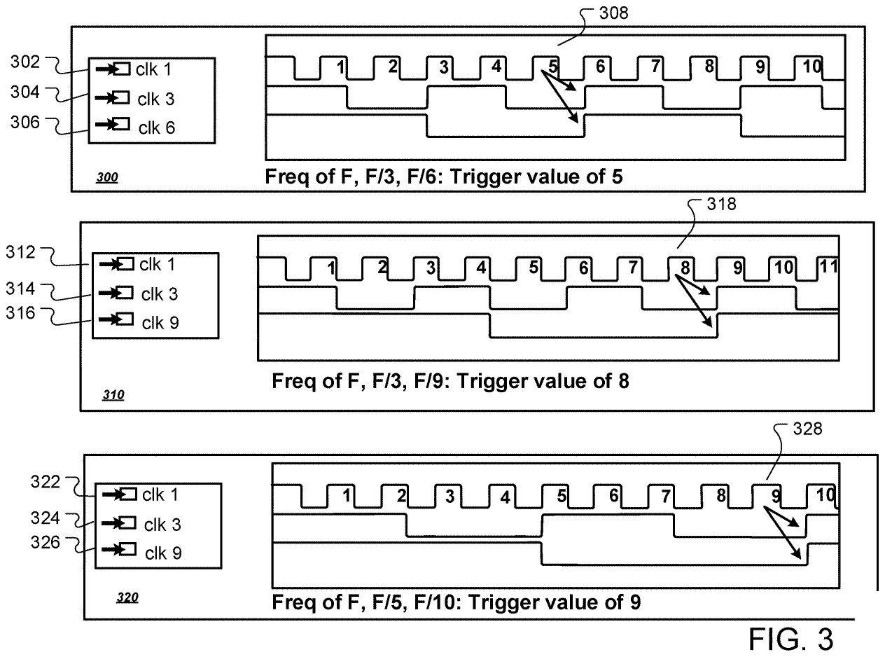

The OEAC 102 can maintain a trigger test data register (TDR) 118 that stores a trigger time delay relay value for each of the OCCs 130a-n that is based on a least common multiple of the frequency ratio of the OCCs 130. The determination of the trigger time delay relay values will be described in more detail below with reference to FIG. 3. The TDR 118 can output the trigger time delay relay values via a trigger count signal, “trigger_cnt” 124.

The OEAC 102 can include comparators 126a, 126b . . . 126n (collectively, “comparators 126”) that compare the counter value signal 122 with the trigger time delay relay values of the trigger count signal 124 for each of the OCCs 130a-n. When the counter value signal 122 is equal to the trigger time delay relay value corresponding to each of the OCCs 130a-n, the OEAC 102 can generate trigger output values 128a, 128b . . . 128n (collectively, “trigger output values 128”) at corresponding trigger output ports 127a, 127b . . . 127n (collectively, “trigger output ports 127”). The OEAC 102 can send the trigger output values 128 to trigger the corresponding OCCs 130.

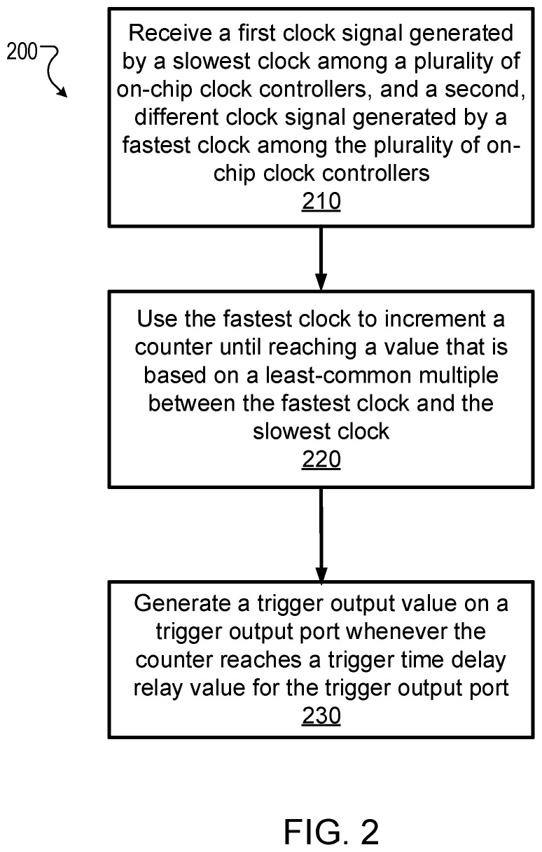

FIG. 2 is a flowchart of an example process 200 for synchronizing OCCs. For convenience, the process 200 will be described as being performed by the OEAC system 100 that includes a plurality of OCCs and an OEAC 102. The system can include the components described in reference to FIG. 1, including one or more computing devices, subsystems, components, or some combination of these.

The OEAC 102 can receive or detect a clock signal generated by the slowest clock among a plurality of OCCs, and a fastest clock among the plurality of OCCs (210). In some implementations, the plurality of OCCs operate at different frequencies. In some implementations, at least two of the different frequencies have a divided clock relationship in which the divisor is not a power of two or is an odd number.

The OEAC 102 can use the fastest clock to increment the counter until reaching a value that is based on a least-common multiple between the fastest clock and the slowest clock (220). In some implementations, the OEAC 102 is configured to synchronize a sampled scan enable signal on the slowest clock to generate an enable signal for the counter. In some implementations, the OEAC 102 includes a sync cell that is configured to receive the sampled scan enable signal and the slowest clock to generate an enable signal that starts the counter incrementing on the fastest clock.

In some implementations, the OEAC 102 can use the fastest clock to increment the counter until reaching a value that is based on a least-common multiple between the fastest clock and the slowest clock and a number of pipeline stages. In some implementations, each trigger output value can be sent across different physical partitions through one or more of the pipeline stages. In some implementations, the number of pipeline stages between the OEAC 102 and each physical partition is based on a distance between the OEAC 102 and the OCCs inside the physical partition.

The OEAC 102 can generate a trigger output value on a trigger output port when the counter reaches the value (230). In some implementations, the OEAC system 100 can generate the plurality of trigger output values to cause the on-chip clock controllers to output aligned clock edges.

FIG. 3 is a diagram of example synchronized clock pulses. These clock pulses are the outputs of the synchronized OCCs 130 of FIG. 1.

Referring back to FIG. 1, the OEAC 102 triggers the OCCs 130 when the counter value signal 122 is equal to the trigger time delay relay value corresponding to each of the OCCs 130a-n that is the least common multiple of the frequency ratio of the OCCs, subtracted by 1.

Digital timing diagram 300 shows three waveforms clk1 302, clk3 304, and clk6 306. Clk1 302 has frequency F, clk3 304 has frequency F/3, and clk6 306 has frequency F/6. The least common multiple of the frequency ratio of the clock pulses in diagram 300 is 6, so the trigger time delay relay value is 5. The values 308 refer to the values of the counter value signal 122 in FIG. 1. The diagram 300 shows that the pulses of the three waveforms are aligned after count 5.

Digital timing diagram 310 shows three waveforms clk1 312, clk3 314, and clk9 316. Clk1 312 has frequency F, clk3 314 has frequency F/3, and clk9 316 has frequency F/9.

As explained above, the least common multiple of the frequency ratio of the clock pulses in diagram 310 is 9, so the trigger time delay relay value is 8. The values 318 refer to the values of the counter value signal 122 in FIG. 1. The diagram 310 shows that the pulses of the three waveforms are aligned after count 8.

Digital timing diagram 320 shows three waveforms clk1 322, clk5 324, and clk10 326. Clk1 322 has frequency F, clk5 324 has frequency F/5, and clk10 326 has frequency F/10.

As explained above, the least common multiple of the frequency ratio of the clock pulses in diagram 320 is 10, so the trigger time delay relay value is 9. The values 328 refer to the values of the counter value signal 122 in FIG. 1. The diagram 320 shows that the pulses of the three waveforms are aligned after count 9.

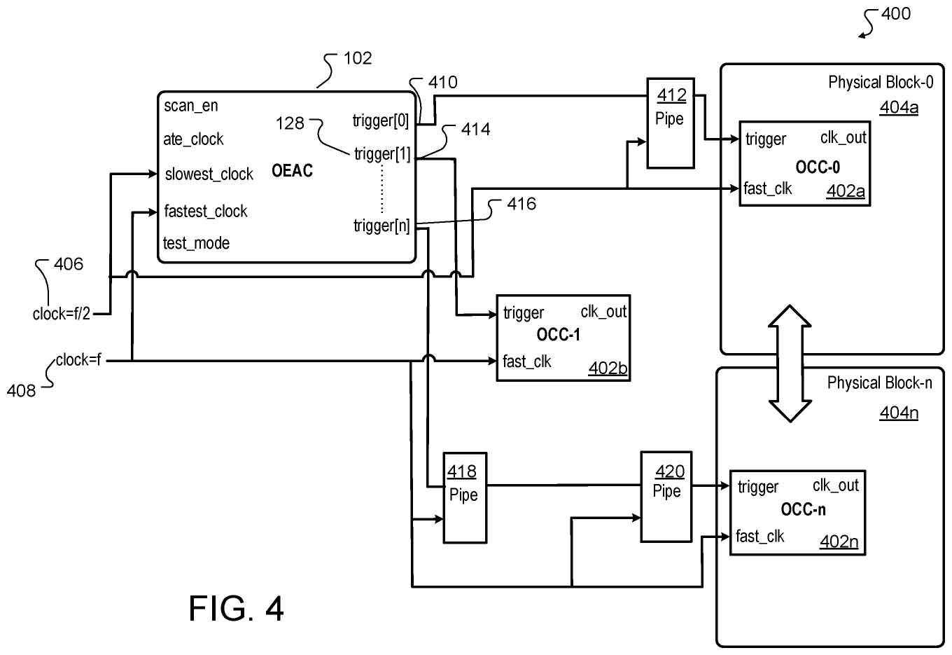

FIG. 4 is a diagram of an example OEAC system 400 that can synchronize OCCs across physical partitions.

OCCs can be located across different physical partitions. For example, OCC-0402a is located in Physical Block-0 404a, and OCC-n 402n is located in Physical Block-n 404n. OCC-1 402b is not located in a separate physical block in FIG. 4, but can be located in a separate physical block in some examples. To meet timing requirements for each OCC, such as OCC-0 402a and OCC-n 402n, across different physical partitions, trigger output values 128 can be pipelined. As described in reference to FIG. 1, the OEAC 102 can send trigger output values 128 on trigger output ports 127 when the counter value signal 122 is equal to the trigger time delay relay value corresponding to each OCC. The trigger time delay relay value is a multiple of the least common multiple of the frequency ratio of the OCCs, subtracted by 1, subtracted by the number of pipeline stages in between the trigger output port and the OCC.

For example in FIG. 4, the slowest clock signal, “slowest_clock” 406, or the clock signal having the lowest frequency among OCC-0 402a and OCC-n 402n, has a frequency F/2. The fastest clock signal, “fastest_clock” 408, or the clock signal having the highest frequency among OCC- 0 402a and OCC-n 402n, has a frequency F. The least common multiple of the frequency ratio between the slowest clock signal 406 and the fastest clock signal 408 is 2. Multiples of 2, for example, 4, 6, and 8, can also be used. The trigger output port connected to OCC-0 402a, “trigger[0]” 410, connects to OCC-0 402a through one pipe, Pipe 412. The trigger time delay relay value for OCC-0 402a can be a value of 6, which is 8 subtracted by 1, subtracted by 1.

The trigger output port connected to OCC-1 402b, “trigger[1]” 414, connects to OCC-1 402b without any pipes. The trigger time delay relay value for OCC-1 402b can be a value of 7, which is 8 subtracted by 1, subtracted by 0.

The trigger output port connected to OCC-n 402n, “trigger[n]” 416, connects to OCC-n 402n through two pipes, Pipe 418 and Pipe 420. The trigger time delay relay value for OCC-n 402n can be a value of 5, which is 8 subtracted by 1, subtracted by 2.

In some implementations, the number of pipeline stages between the OEAC 102 and each physical partition can be based on a distance between the OEAC 102 and the physical partition. For example, Physical Block-n 404n is located farther from the OEAC 102 than Physical Block-0 404a. Thus, there are two pipes 418 and 420 in between the OEAC 102 and Physical Block-n 404n, and there is one pipe 412 in between the OEAC 102 and Physical Block-0 404a. OCC-1 402b is not located in a separate physical block, and there are no pipes in between the OEAC 102 and the OCC-1 402b.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them.

Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program which may also be referred to or described as a program, software, a software application, an app, a module, a software module, a script, or code) can be written in any form of programming language, including compiled or interpreted languages, or declarative or procedural languages, and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and pointing device, e. g, a mouse, trackball, or a presence sensitive display or other surface by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone, running a messaging application, and receiving responsive messages from the user in return.

In addition to the embodiments described above, the following embodiments are also innovative:

Embodiment 1 is a device comprising:
a plurality of on-chip clock controllers; and
an on-chip edge alignment controller comprising:
   a counter, and
   a plurality of trigger output ports corresponding respectively to each of the plurality of on-chip clock controllers, wherein each trigger output port has a corresponding trigger time delay relay value,
wherein the on-chip edge alignment controller is configured to receive a first clock signal generated by a slowest clock among the plurality of on-chip clock controllers, a second, different clock signal generated by a fastest clock among the plurality of on-chip clock controllers, and
wherein the on-chip edge alignment controller is configured to use the fastest clock to increment the counter until reaching a value that is based on a least-common multiple between the fastest clock and the slowest clock and configured to generate a trigger output value on a trigger output port when the counter reaches the value.

Embodiment 2 is the device of embodiment 1, wherein the device generates the plurality of trigger output values to cause the on-chip clock controllers to output aligned clock edges.

Embodiment 3 is the device of any one of the embodiments 1-2, wherein the plurality of on-chip clock controllers operate at different frequencies.

Embodiment 4 is the device of embodiment 3, wherein at least two of the different frequencies have a divided clock relationship in which the divisor is not a power of two or is an odd number.

Embodiment 5 is the device of any one of embodiments 1-4, wherein the on-chip edge alignment controller is configured to synchronize a sampled scan enable signal on the slowest clock to generate an enable signal for the counter.

Embodiment 6 is the device of embodiment 5, further comprising a sync cell that is configured to receive the sampled scan enable signal and the slowest clock to generate an enable signal that starts the counter incrementing on the fastest clock.

Embodiment 7 is the device of any one of embodiments 1-6, wherein the value is based on a least-common multiple between the fastest clock and the slowest clock and a number of pipeline stages.

Embodiment 8 is the device of embodiment 7, wherein each trigger output value can be sent across different physical partitions through one or more of the pipeline stages.

Embodiment 9 is the device of embodiment 8, wherein the number of pipeline stages between the on-chip edge alignment controller and each physical partition is based on a distance between the on-chip edge alignment controller and the on-chip clock controllers inside the physical partition.

Embodiment 10 is a method performed by a device comprising:
a plurality of on-chip clock controllers; and
an on-chip edge alignment controller,
the method comprising:
detecting, by the on-chip edge alignment controller, a scan enable signal;
receiving, by the on-chip edge alignment controller, a first clock signal generated by a slowest clock among the plurality of on-chip clock controllers;
receiving, by the on-chip edge alignment controller, a second, different clock signal generated by a fastest clock among the plurality of on-chip clock controllers;
incrementing, by the on-chip edge alignment controller using the fastest clock, a counter;
determining that the counter has reached a value that is based on a least-common multiple between the fastest clock and the slowest clock; and
in response to determining that the counter has reached the value that is based on the least-common multiple between the fastest clock and the slowest clock, generating a trigger output value on a trigger output port.

Embodiment 11 is the method of embodiment 10, further comprising generating the plurality of trigger output values to cause the on-chip clock controllers to output aligned clock edges.

Embodiment 12 is the method of any one of embodiments 10-11, wherein the plurality of on-chip clock controllers operate at different frequencies.

Embodiment 13 is the method of embodiment 12, wherein at least two of the different frequencies have a divided clock relationship in which the divisor is not a power of two or is an odd number.

Embodiment 14 is the method of any one of embodiments 10-13, further comprising synchronizing a sampled scan enable signal on the slowest clock to generate an enable signal for the counter.

Embodiment 15 is the method of embodiment 14, wherein the device further comprises a sync cell that is configured to receive the sampled scan enable signal and the slowest clock to generate an enable signal that starts the counter incrementing on the fastest clock.

Embodiment 16 is the method of any one of embodiments 10-15, wherein the value is based on a least-common multiple between the fastest clock and the slowest clock and a number of pipeline stages.

Embodiment 17 is the method of embodiment 16, wherein each trigger output value can be sent across different physical partitions through one or more of the pipeline stages.

Embodiment 18 is the method of embodiment 17, wherein the number of pipeline stages between the on-chip edge alignment controller and each physical partition is based on a distance between the on-chip edge alignment controller and the on-chip clock controllers inside the physical partition.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

What is claimed is:

1. A device comprising:
a plurality of on-chip clock controllers; and
an on-chip edge alignment controller comprising:
a counter, and
a plurality of trigger output ports corresponding respectively to each of the plurality of on-chip clock controllers, wherein each trigger output port has a corresponding trigger time delay relay value,
wherein the on-chip edge alignment controller is configured to receive a first clock signal generated by a slowest clock among the plurality of on-chip clock controllers, a second, different clock signal generated by a fastest clock among the plurality of on-chip clock controllers, and
wherein the on-chip edge alignment controller is configured to use the fastest clock to increment the counter until reaching a value that is based on a least-common multiple between the fastest clock and the slowest clock and configured to generate a trigger output value on a trigger output port when the counter reaches the value.

2. The device of claim 1, wherein the device generates the plurality of trigger output values to cause the on-chip clock controllers to output aligned clock edges.

3. The device of claim 1, wherein the plurality of on-chip clock controllers operate at different frequencies.

4. The device of claim 3, wherein at least two of the different frequencies have a divided clock relationship in which the divisor is not a power of two or is an odd number.

5. The device of claim 1, wherein the on-chip edge alignment controller is configured to synchronize a sampled scan enable signal on the slowest clock to generate an enable signal for the counter.

6. The device of claim 5, further comprising a sync cell that is configured to receive the sampled scan enable signal and the slowest clock to generate an enable signal that starts the counter incrementing on the fastest clock.

7. The device of claim 1, wherein the value is based on a least-common multiple between the fastest clock and the slowest clock and a number of pipeline stages.

8. The device of claim 7, wherein each trigger output value can be sent across different physical partitions through one or more of the pipeline stages.

9. The device of claim 8, wherein the number of pipeline stages between the on-chip edge alignment controller and each physical partition is based on a distance between the on-chip edge alignment controller and the on-chip clock controllers inside the physical partition.

10. A method performed by a device comprising:
a plurality of on-chip clock controllers; and
an on-chip edge alignment controller,
the method comprising:
detecting, by the on-chip edge alignment controller, a scan enable signal;
receiving, by the on-chip edge alignment controller, a first clock signal generated by a slowest clock among the plurality of on-chip clock controllers;
receiving, by the on-chip edge alignment controller, a second, different clock signal generated by a fastest clock among the plurality of on-chip clock controllers;
incrementing, by the on-chip edge alignment controller using the fastest clock, a counter;
determining that the counter has reached a value that is based on a least-common multiple between the fastest clock and the slowest clock; and
in response to determining that the counter has reached the value that is based on the least-common multiple between the fastest clock and the slowest clock, generating a trigger output value on a trigger output port.

11. The method of claim 10, further comprising generating the plurality of trigger output values to cause the on-chip clock controllers to output aligned clock edges.

12. The method of claim 10, wherein the plurality of on-chip clock controllers operate at different frequencies.

13. The method of claim 12, wherein at least two of the different frequencies have a divided clock relationship in which the divisor is not a power of two or is an odd number.

14. The method of claim 10, further comprising synchronizing a sampled scan enable signal on the slowest clock to generate an enable signal for the counter.

15. The method of claim 14, wherein the device further comprises a sync cell that is configured to receive the sampled scan enable signal and the slowest clock to generate an enable signal that starts the counter incrementing on the fastest clock.

16. The method of claim 10, wherein the value is based on a least-common multiple between the fastest clock and the slowest clock and a number of pipeline stages.

17. The method of claim 16, wherein each trigger output value can be sent across different physical partitions through one or more of the pipeline stages.

18. The method of claim 17, wherein the number of pipeline stages between the on-chip edge alignment controller and each physical partition is based on a distance between the on-chip edge alignment controller and the on-chip clock controllers inside the physical partition.
